(19) United States
(12) Patent Application Publication
(10) Pub. No.: US 2017/0040391 A1
(43) Pub. Date: Feb. 9, 2017

(54) ORGANIC LIGHT EMITTING DIODE MODULE WITH OPTICAL SIGNAL TRANSMISSION

(71) Applicant: WiseChip Semiconductor Inc., Miaoli County (TW)

(72) Inventors: CHIEN-LE LI, Miaoli County (TW); YUNG-CHENG TSAI, Miaoli County (TW); CHIEN-HSUN CHEN, Miaoli County (TW)

(21) Appl. No.: 14/818,894

(22) Filed: Aug. 5, 2015

(51) Int. Cl. H01L 27/32; H01L 51/52

(52) U.S. Cl. CPC H01L 27/3227; H01L 27/3225; H01L 51/5271; H01L 51/5253; H01L 2251/5361

(57) ABSTRACT

An organic light emitting diode (OLED) module with optical signal transmission includes a substrate, an OLED element, an optical signal transmission element and a spacing member. The substrate includes a light emitting region, an optical transmission region, and a spacing region spaced between the light emitting region and an optical transmission region. The OLED element is disposed in the light emitting region, and includes a first electrode layer, a second electrode layer and an organic light emitting layer. The optical signal transmission element is disposed in the optical transmission region and transmits an optical signal to the exterior. The spacing member is disposed in the spacing region, and includes a lower portion and an upper portion having a width greater than that of the lower portion. Thus, the present invention provides a simplified manufacturing process, a reduced overall volume and lowered production costs.

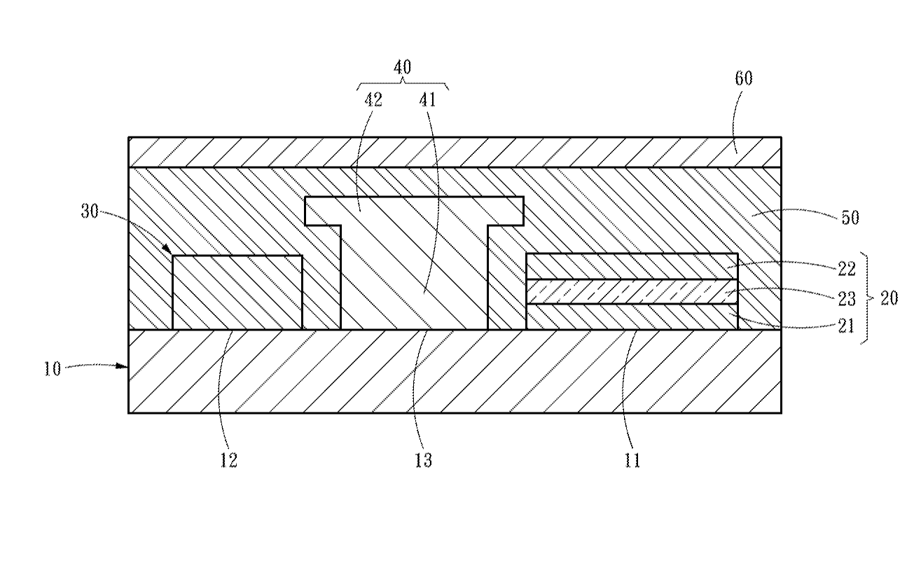

### FIELD OF THE INVENTION

The present invention relates to an organic light emitting diode (OLED), and particularly to an OLED with optical signal transmission.

### BACKGROUND OF THE INVENTION

Light emitting diodes (LEDs), featuring advantages of low power consumption and long life cycle, are gradually replacing conventional incandescent light bulbs and fluorescent light that suffer from large power consumption, short life cycle and lack of environmental friendliness. Therefore, being highly valued by associated industrialists and the public, LEDs have become the premium choice for light sources of various lighting apparatuses.

For example, the U.S. Pat. No. 7,318,658 discloses a high power LED color bulb with infrared remote function including a reflector, an LED module with color LED chips, and a bulb cover with a controlling circuit board. The LED module is mounted on a rear end of the reflector to have the LED chips inside the reflector. The bulb cover is mounted on a rear end of the reflector. The LED module is connected to the controlling circuit board. The reflector has a light guide hole or a light guide bar, which extends backwards from a front end of the reflector to correspondingly control an infrared sensor on the controlling circuit board to form the LED color bulb with infrared remote function. Thus, without providing the infrared sensor at the front end of the reflector, infrared signals coming from the front of the reflector can be received through the light guide hole or the light guide bar, so as to control switching on/off, color, change mode and brightness of the color bulb.

However, for such type of LED product with optical signal transmission, as the LED module and the infrared sensor are first separately assembled and manufactured, and then integrated and correspondingly mounted on the controlling circuit board, the LED product has not only a more complicated manufacturing process but also a volume that cannot be further reduced. Further, with the rapid development of OLED manufacturing technologies, compared to LEDS, advantages of better feasibility for large-size manufacturing and lower production costs of OLEDs are emphasized. Therefore, there is a need for a solution for improving the above type of LED product with optical signal transmission.

### SUMMARY OF THE INVENTION

The primary object of the present invention is to solve issues of a complicated manufacturing process, a volume that cannot be easily reduced and high production costs of a conventional light emitting diode (LED) product with optical signal transmission.

To achieve the above object, the present invention provides an organic light emitting diode (OLED) module with optical signal transmission. The OLED module with optical signal transmission includes a substrate, an OLED element, an optical signal transmission element and a spacing member. The substrate includes a light emitting region, an optical transmission region, and a spacing region spaced between the light emitting region and the optical transmission region. The OLED element is disposed in the light emitting region, and includes a first electrode layer located on the substrate, a second electrode layer away from the substrate, and an organic light emitting layer disposed between the first electrode layer and the second electrode layer. The optical signal transmission element is disposed in the optical transmission region, and transmits an optical signal to the exterior. The spacing member is disposed in the spacing region, and includes a lower portion and an upper portion having a width greater than that of the lower portion.

As such, by disposing the OLED element and the optical signal transmission element on the substrate, the present invention integrates the LED element and the optical transmission element in a same manufacturing process. Therefore, compared to a conventional LED product, the OLED module provides a simplified manufacturing process, a reduced overall volume and lowered production costs.

### BRIEF DESCRIPTION OF THE DRAWINGS

The sole FIGURE is a section view according to an embodiment of the present invention.

### DETAILED DESCRIPTION OF THE PREFERRED

### Embodiments

Detailed description and technical contents of the present invention are given with the accompanying drawings below.

The FIGURE shows a section view according to an embodiment of the present invention. As shown, the present invention is organic light emitting diode (OLED) module with optical signal transmission includes a substrate 10, an OLED element 20, an optical signal transmission element 30 and a spacing member 40. The substrate 10 may be transparent or opaque, and may be made from a material such as glass, plastic, silicon, graphene, gallium arsenide (GaAs), gallium nitride (GaN) or silicon carbide (SiC). The substrate 10 includes a light emitting region 11, an optical transmission region 12 and a spacing region 13. The light emitting region 11, the optical transmission region 12 and the spacing region 13 are disposed at a same side of the substrate 10. The spacing region 13 is disposed between the light emitting region 11 and the optical transmission region 12.

The OLED element 20 is disposed in the light emitting region 11, and includes a first electrode layer 21, a second electrode layer 22 and an organic light emitting layer 23. The first electrode layer 21 is located on the substrate 10, and may be made of a material such as a metal film, a metal compound film, a ceramic material, or a high-polymer conductive material. For example, the metal film may be gold (Au), silver (Ag), platinum (Pt), copper (Cu), aluminium (Al), chromium (Cr), palladium (Pd) or rhodium (Rh). Preferably, the metal compound film has a thickness smaller than 250 nm, and may be a metal oxide, a metal nitride or a metal fluoride, e.g., a indium-containing metal oxide such as indium tin oxide (ITO) or indium gallium zinc oxide (IGZO), or a non-indium-containing metal oxide such as aluminium oxide or zinc oxide. For example, the ceramic material may be carbon nanotubes or graphene, and the high-polymer conductive material may be PEDOT:PSS or other high-polymer materials with electrical conductivity. The second electrode layer 22 is located at one side of the substrate 10 away from the first electrode layer 21, and may be made of a material such as a metal film, a metal compound film, or a non-metal material. For example, the metal film may be gold (Au), silver (Ag), platinum (Pt), copper (Cu), aluminium (Al), chromium (Cr), palladium (Pd) or rhodium (Rh). Preferably, the metal compound film has a thickness smaller than 250 nm, and may be a metal oxide, a metal nitride or a metal fluoride, e.g., a indium-containing metal oxide such as indium tin oxide (ITO) or indium gallium zinc oxide (IGZO), or a non-indium-containing metal oxide such as aluminium oxide or aluminium zinc oxide. For example, the non-metal material may be carbon nanotubes, graphene, nanosilver, or a high-polymer conductive material (e.g., PEDOT:PSS). The organic light emitting layer 23 is disposed between the first electrode layer 21 and the second electrode layer 22, and includes a hole transmission layer, an electron transmission layer and a light emitting layer. The hole transmission layer, connected to the first electrode layer 21, may be made of a dopable transmission material having a high hole mobility, e.g., an organic compound or an organic metal compound. The organic compound may include a multi-carbon functional group such as an aromatic amine or a benzene functional group, e.g., HAT-CN, NPB CuPc. The electron transmission layer is located at one side of the hole transmission layer away from the first electrode layer 21, and may be made of a dopable transmission material having a high electron mobility, e.g., an organic compound or an organic metal compound. The organic compound may be a multi-carbon and heterocyclic functional group, e.g., an aromatic amine or a benzene functional group and silicon (Si) or nitrogen (N). The organic metal compound may be Alq3 or BeBq2. The light emitting layer is disposed between the hole transmission layer and the electron transmission layer. In the present invention, the light emitting layer is a structure formed by a single film or multiple films. The organic light emitting layer 23 may provide the hole transmission layer and the electron transmission layer with an external bias through the first electrode layer 21 and the second electrode layer 22, such that the hole transmission layer and the electron transmission layer generate a plurality of holes and a plurality of electrons, respectively. The holes and the electrons enter the light emitting layer to release energy in form of a visible light, which passes through the substrate 10 and becomes emitted.

The optical signal transmission element 30, disposed in the optical transmission region 12, transmits an optical signal to the exterior, and includes an optical transmitter or an optical receiver. When the optical signal transmission element 30 includes an optical transmitter, the optical transmitter may transmit an optical signal. When the optical signal transmission element 30 includes an optical receiver, the optical receiver may receive an optical signal. For example, the optical signal is an infrared signal or a visible light having a wavelength between 400 nm and 700 nm, for example.

The spacing member 40 is disposed in the spacing region 13, and includes a lower portion 41 and an upper portion 42. A width of the upper portion 42 is greater than that of the lower portion 41, and a height of the upper portion 42 is higher than that of the OLED element 20. In the embodiment, for example, the spacing member 40 has a T-shaped cross section. In other embodiments, the spacing member 40 may have a trapezoidal cross section, or a cross section with a planar contour that renders the width of the upper portion 42 to be greater than that of the lower portion 41.

In the embodiment, the OLED module may further include a protecting layer 50 and a reflecting layer 60. The protecting layer 50 covers the OLED element 20, the optical signal transmission element 30 and the spacing member 40, and may be made of a material such as an organic compound, an organic polymer, an inorganic polymer, an inorganic oxide or an inorganic oxide. For example, an organic compound may be a perylene derivative, and an inorganic oxide may be silicon oxide (SiO₂), silicon nitride (SiNx) or titanium oxide (TiOx), so as to prevent the OLED element 20 and the optical signal transmission element 30 from moisture invasion. The reflecting layer 60 covers the protecting layer 50, and may be made of a material such as an organic compound, an organic polymer, an inorganic polymer, an inorganic oxide or an inorganic nitride. For example, an organic compound may be a perylene derivative, and an inorganic oxide may be silicon oxide (SiO₂), silicon nitride (SiNx) or titanium oxide (TiOx), so as to increase the light extraction rate of the OLED element 20 facing the substrate 10.

As such, with the above structure, the present invention is applicable to various lighting products involving optical signal transmission. For example, when the present invention is applied to a lighting device, the optical signal transmission element 30 may include the optical receiver, which receives the optical signal transmitted from a remote end. The OLED module may then control operations of the OLED element 20 according to an instruction the optical signal transmits. For another example, when the present invention is applied to a remote controller, the OLED element 20 may be an operation screen or a key region providing a display light source on the remote controller. The optical transmitter may transmit an operation instruction set by the operation screen or the key region to drive an apparatus associated with the remote controller.

In conclusion, by disposing the OLED element and the optical signal transmission element on the substrate as well as providing the spacing member, the present invention integrates the LED element and the optical transmission element in a same manufacturing process. Therefore, compared to a conventional LED product, the OLED module provides a simplified manufacturing process, a reduced overall volume and lowered production costs, thereby enhancing the application advantage of the present invention to various lighting products involving optical signal transmission.

What is claimed is:

1. An organic light emitting diode (OLED) module with optical signal transmission, comprising:
a substrate, comprising a light emitting region, an optical transmission region, and a spacing region between the light emitting region and the optical transmission region;
an organic light emitting diode (OLED) element, disposed in the light emitting region, comprising a first electrode layer located on the substrate, a second electrode layer away from the substrate, and an organic light emitting layer disposed between the first electrode layer and the second electrode layer;
an optical signal transmission element, disposed in the optical transmission region, transmitting an optical signal to an exterior; and
a spacing member, disposed in the spacing region, comprising a lower portion and an upper portion having a width greater than that of the lower portion.

2. The OLED module with optical signal transmission of claim 1, wherein the optical signal is an infrared signal or a visible light with a wavelength between 400 nm and 700 nm.

3. The OLED module with optical signal transmission of claim 1, wherein the optical signal transmission element comprises an optical transmitter that transmits the optical signal.

4. The OLED module with optical signal transmission of claim 1, wherein the optical signal transmission element comprises an optical receiver that receives the optical signal.

5. The OLED module with optical signal transmission of claim 1, wherein the upper portion has a height higher than that of the OLED element.

6. The OLED module with optical signal transmission of claim 1, further comprising:
a protecting layer, covering the OLED element, the optical signal transmission element and the spacing member.

7. The OLED module with optical signal transmission of claim 6, further comprising:
a reflecting layer, covering the protecting layer.
